(19) United States
(12) Patent Application Publication
(10) Pub. No.: US 2024/0376634 A1
(43) Pub. Date: Nov. 14, 2024

(54) LIQUID PRECURSOR CONTAINERS, LIQUID PRECURSOR SYSTEMS AND SEMICONDUCTOR PROCESSING SYSTEMS HAVING LIQUID PRECURSOR CONTAINERS, AND METHODS OF DEPOSITING MATERIAL LAYERS USING LIQUID PRECURSORS

(71) Applicant: ASM IP Holding B.V., Almere (NL)

(72) Inventors: Krishnaswamy Mahadevan, Tempe, AZ (US); Fan Gao, Chandler, AZ (US); Peipei Gao, Chandler, AZ (US); Xing Lin, Chandler, AZ (US)

(21) Appl. No.: 18/660,652

(22) Filed: May 10, 2024

Related U.S. Application Data
(60) Provisional application No. 63/501,382, filed on May 10, 2023.

(51) Int. Cl. C30B 25/14; C30B 25/16

(52) U.S. Cl. CPC C30B 25/14; C30B 25/165

(57) ABSTRACT

A liquid precursor container includes an inner container, an outer container, and a baffle member. The inner container has an inner base portion, an inner intermediate portion extending from the inner base portion, and an inner lid portion coupled to the inner base portion by the inner intermediate portion. The outer container envelops the inner container and has an outer base portion spaced apart from the inner base portion, an outer intermediate portion extending from the outer base portion and about the inner intermediate portion of the inner container, and an outer lid portion coupled to the outer base portion by the outer intermediate portion of the outer container. The baffle member is arranged between the inner lid portion of the inner container and the outer lid portion of the outer container to circulate liquid coolant about the inner container to cool a liquid precursor contained within the inner container.

### CROSS-REFERENCE TO RELATED APPLICATION(S)

This Application claims the benefit of U.S. Provisional Application 63/501,382 filed on May 10, 2023, the entire contents of which are incorporated herein by reference.

### FIELD OF INVENTION

The present disclosure relates to fabricating semiconductor devices, and more particularly, to depositing material layers onto substrates using semiconductor processing systems.

### BACKGROUND OF THE DISCLOSURE

Material layers are commonly deposited onto substrates during the fabrication of semiconductor devices using gas phase reactors, such as during the fabrication of integrated circuit and power electronic semiconductor devices. Material layer deposition is generally accomplished by supporting a substrate within the reactor, heating the substrate to a desired material layer deposition temperature, and exposing the substrate to one or more material layer precursors. Exposure to the material layer precursor is typically accomplished under environmental and flow conditions selected to cause a material layer having a desired composition to deposit onto the substrate, generally by exposing the substrate to a desired vapor delivery rate of material layer precursor for a desired deposition interval. Once the material layer reaches a desired thickness, the substrate is typically removed from the reactor and sent on for further processing.

In some deposition processes, it may be advantageous to employ a liquid material layer precursor in the deposition process, i.e., a precursor that adopts a liquid state under standard atmospheric temperature and pressure. For example, some silicon-containing liquid material layer precursors have greater numbers of silicon atoms per molecule than gaseous phase silicon-containing material layer precursors, enabling greater throughput and/or lower deposition temperatures. Certain dopant-containing liquid material layer precursors may be less hazardous to human health than gaseous dopant-containing alternatives, potentially simplifying the semiconductor processing system employed for deposition by limiting the need for safety countermeasures otherwise required for the gaseous dopant-containing alternatives.

One challenge to employing liquid material precursors in gas phase reactors is the need to convert the liquid material layer precursor into a gaseous state while maintaining accurate vapor delivery rate. Typically, liquid-to-vapor conversion is accomplished by partially filling a container with a liquid material and bubbling a carrier gas through the liquid. As the carrier gas bubbles through the liquid a portion of the liquid is vaporized, the vaporized liquid providing a source of source of vaporize liquid for delivery to a point of use. Vapor delivery rate from such bubblers may be controlled using thermal conductivity mass flow meters, which monitor mass flow from the bubblers using a ratio of carrier gas thermal conductivity and the vaporized liquid precursor/carrier thermal conductivity. While generally satisfactory for their intended purpose, thermal conductivity ratio-based techniques are sensitive to temperature of the liquid contained within the bubbler, and may drift as the thermal mass of the liquid changes during vaporization of the liquid contained within the bubbler. The drift may be such that vapor delivery rate accuracy is insufficient for control of certain material layer deposition techniques, such as those employed to fabricate semiconductor devices intolerant of material layer thickness variation associated with vapor delivery rate inaccuracy.

Such systems and methods have generally been considered suitable for their intended purpose. However, there remains a need in the art for improved liquid precursor containers, liquid delivery and semiconductor processing systems, and methods of depositing material layers. The present disclosure provides a solution to this need.

### SUMMARY OF THE DISCLOSURE

A liquid precursor container is provided. A liquid precursor container includes an inner container, an outer container, and a baffle member. The inner container has an inner base portion, an inner intermediate portion extending from the inner base portion, and an inner lid portion coupled to the inner base portion by the inner intermediate portion. The outer container envelops the inner container and has an outer base portion spaced apart from the inner base portion of the inner container, an outer intermediate portion extending from the outer base portion and about the inner intermediate portion of the inner container, and an outer lid portion coupled to the outer base portion by the outer intermediate portion of the outer container. The baffle member is arranged between the inner lid portion of the inner container and the outer lid portion of the outer container to circulate a liquid coolant about the inner container to cool a liquid precursor contained within the inner container during vaporization of the liquid precursor.

In addition to one or more of the features described above, or as an alternative, further examples may include that the liquid precursor contained within the liquid precursor container includes a silicon-containing liquid precursor for an epitaxial deposition technique.

In addition to one or more of the features described above, or as an alternative, further examples may include that the liquid precursor contained within the liquid precursor container includes a dopant-containing liquid precursor for an epitaxial deposition technique.

In addition to one or more of the features described above, or as an alternative, further examples may include that the liquid precursor contained within the inner container includes at least one of trisilane (Si₃H₆), tetrasilane (Si₄H₁₀), and tertiarybutylarsine (C₄H₁₁As).

In addition to one or more of the features described above, or as an alternative, further examples of the liquid precursor container may include a probe member extending through the outer lid portion of outer container and the inner lid portion of the inner container to provide a precursor temperature measurement and a precursor level measurement of the liquid precursor container within the inner container.

In addition to one or more of the features described above, or as an alternative, further examples of the liquid precursor container may include a carrier gas conduit extending through the outer lid portion of the outer container and the inner lid portion of the inner container to vaporize the liquid precursor using a carrier gas issued into the liquid precursor by the carrier gas conduit.

In addition to one or more of the features described above, or as an alternative, further examples of the liquid precursor container may include a refill conduit extending through the outer lid portion of the outer container and the inner lid portion of the inner container to refill the inner container with the liquid precursor when level of the liquid precursor falls below a predetermined liquid precursor level.

In addition to one or more of the features described above, or as an alternative, further examples of the liquid precursor container may include a coolant supply conduit, a coolant return conduit, and a coolant pump. The coolant supply conduit may connect to the outer lid portion of the outer container, the coolant return conduit may be connected to the outer lid portion of the outer container and fluidly coupled to the coolant supply conduit by an exterior surface of the inner container; and the coolant pump connected to the coolant supply conduit and the coolant return conduit to circulate the liquid coolant about the exterior surface of the inner container. The baffle member may separate the coolant return conduit from the coolant supply conduit.

In addition to one or more of the features described above, or as an alternative, further examples of the liquid precursor container may include a chill plate fluidly coupling the coolant supply conduit to the coolant return conduit to transfer heat between the liquid precursor contained within the inner container and an external environment outside of the liquid precursor container.

In addition to one or more of the features described above, or as an alternative, further examples of the liquid precursor container may include a thermoelectric cooler thermally coupled to the liquid precursor by the coolant supply conduit and the coolant return conduit to throttle rate of heat transfer between the liquid precursor contained within the liquid precursor container and an external environment outside of the liquid precursor container.

In addition to one or more of the features described above, or as an alternative, further examples of the liquid precursor container may include an outlet conduit extending through the outer lid portion of the outer container and seated in the inner lid portion of the inner container to fluidly couple a gas phase reactor to a precursor ullage space defined between the liquid precursor and the inner lid portion of the inner container.

In addition to one or more of the features described above, or as an alternative, further examples of the liquid precursor container may include a vapor pressure concentration sensor connected to the outlet conduit to provide a precursor concentration measurement from vaporized liquid precursor traversing the outlet conduit.

In addition to one or more of the features described above, or as an alternative, further examples of the liquid precursor container may include a vaporized liquid precursor mass flow controller arranged along the outlet conduit to throttle flow rate of vaporized liquid precursor traversing the outlet conduit.

In addition to one or more of the features described above, or as an alternative, further examples of the liquid precursor container may include a gas phase reactor having a single-wafer crossflow arrangement connected to the outlet conduit to deposit a material layer onto a substrate seated within the gas phase reactor using an epitaxial deposition technique with the vaporized liquid precursor traversing the outlet conduit.

In addition to one or more of the features described above, or as an alternative, further examples of the liquid precursor container may include a controller including a processor and a memory connected to the liquid precursor container. The processor may be responsive to instructions recorded on the memory to receive a liquid precursor temperature measurement, compare the liquid precursor temperature to a predetermined liquid precursor temperature value, and throttle heat transfer between the liquid precursor and an external environment outside of the liquid precursor container based on a differential between the liquid precursor temperature measurement and the predetermined liquid precursor temperature value. Partial pressure of vaporized liquid precursor within a flow of vaporized liquid precursor issued from the liquid precursor container is within a range within which a vapor pressure concentration sensor fluidly coupled to the flow is linear.

In addition to one or more of the features described above, or as an alternative, further examples of the liquid precursor container may include that the instructions recorded on the memory further cause the controller to receive a liquid precursor level measurement indicative of level of the liquid precursor contained within the inner container and adjust the predetermined liquid precursor temperature value using the liquid precursor level measurement, the partial pressure of the vaporized liquid precursor within the flow remaining within the range during drawdown of the liquid precursor contained within the inner container.

In addition to one or more of the features described above, or as an alternative, further examples of the liquid precursor container may include that the instructions recorded on the memory further cause the controller to receive a liquid precursor level measurement indicative of level of the liquid precursor contained within the inner container, compare the liquid precursor level measurement to a predetermined liquid precursor value, and refill the inner container with the liquid precursor when the liquid precursor level measurement is less than the predetermined liquid precursor value.

In addition to one or more of the features described above, or as an alternative, further examples of the liquid precursor container may include the baffle member may divide a gap defined between the outer container and the inner container into a coolant supply plenum extending between the inner lid portion and the inner base portion of the inner container, a coolant return plenum extending between the inner base portion and the inner lid portion of the inner container, and a turning plenum defined between the outer base portion of the outer container and the inner base portion of the inner container. The turning plenum may fluidly couple the coolant return plenum to the coolant supply plenum.

A liquid precursor system is provided. The liquid precursor system includes an enclosure body, first and second liquid precursor containers as described above, a changeover arrangement, and a controller. The enclosure body has an upper chamber and a lower chamber, the first liquid precursor container and the second liquid precursor container are arranged in the upper chamber of the enclosure body, and the changeover arrangement connects the first liquid precursor container and the second liquid precursor container to a precursor supply conduit. The controller is operably connected to the changeover arrangement and responsive to instructions recorded on a memory to receive a liquid precursor level measurement from the first liquid precursor container, fluidly couple the second liquid precursor container to the precursor supply conduit using the changeover arrangement when the liquid precursor level measurement is less than a predetermined liquid precursor level, and refill the first liquid precursor container when the liquid precursor level measurement is less than the predetermined liquid precursor level.

A semiconductor processing system is provided. The semiconductor processing system includes a liquid precursor container as described above, a precursor supply conduit connected to the liquid precursor container, and a gas phase reactor connected to the precursor supply conduit and therethrough to the liquid precursor container.

In addition to one or more of the features described above, or as an alternative, further examples of the semiconductor processing system may include that the liquid precursor container is spaced apart from the gas phase reactor by less than about 3 meters.

A material layer deposition method is provided. The method includes, at a liquid precursor container as described above, vaporizing a liquid precursor contained within the inner container using a carrier gas, flowing the vaporized liquid precursor to a gas phase reactor, and depositing a material layer onto a substrate using an epitaxial technique with the vaporized liquid precursor. A liquid coolant is circulated about the inner container and through the liquid precursor container, and heat transferred between the liquid precursor and an external environment using the liquid coolant to limit partial pressure of precursor in the flow of vaporized liquid precursor to within a partial pressure range wherein a vapor pressure concentration sensor responds linearly to precursor partial pressure change in the flow of vaporized liquid precursor.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a schematic diagram of a semiconductor processing system in accordance with the present disclosure, showing a liquid precursor system providing a flow of vaporized liquid precursor from a liquid precursor container to a gas phase reactor;

FIG. 2 is a side view of the gas phase reactor of FIG. 1 according to an example of the present disclosure, schematically showing a single-wafer crossflow gas phase reactor receiving the flow of vaporized liquid precursor from the liquid precursor system;

FIG. 3 is a side view of the liquid precursor system of FIG. 1 according to another example of the present disclosure, schematically showing a ventilated cabinet with a chiller having a TEC and a liquid precursor container configured for in-situ refilling arranged within the cabinet;

FIG. 4 is an exploded view of the liquid precursor container of FIG. 1 according to an example of the present disclosure, schematically showing an inner lid portion and an external lid portion exploded away from the liquid precursor container;

FIG. 5 is a plan view of the view of the inner lid portion of the inner container of the liquid precursor container of FIG. 1, schematically showing apertures to communicate fluids into and out of the inner container;

FIG. 6 is a plan view of the view of the outer lid portion of the outer container of the liquid precursor container of FIG. 1, schematically showing apertures to communicate fluids into and out of the inner container as well as to circulate coolant about an exterior of the inner container of the liquid precursor container;

FIG. 7 is a cross-sectional sectional view of the liquid precursor container of FIG. 1 according to an example of the present disclosure, schematically showing a liquid precursor contained within the inner container being vaporized with a carrier gas while being cooled using a liquid coolant circulated through the outer container;

FIG. 8 is a block diagram of inputs and outputs to a controller of the liquid precursor system of FIG. 1, schematically showing liquid precursor temperature measurements and liquid level measurements being used to control temperature of the liquid precursor and initiate refilling of the inner container with liquid precursor; and

FIGS. 9-12 are a block diagram of a method of depositing a material layer onto a substrate seated within a gas phase reactor using a liquid precursor, showing operations of the method according to an illustrative and non-limiting example of the method.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

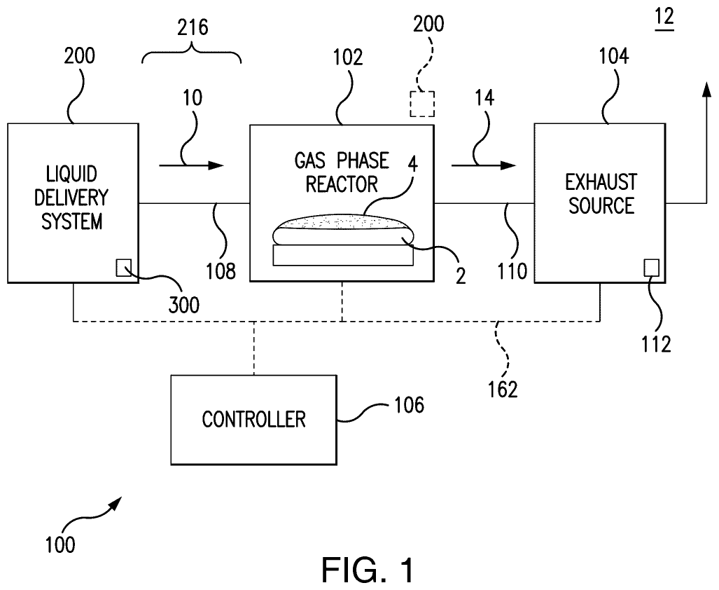

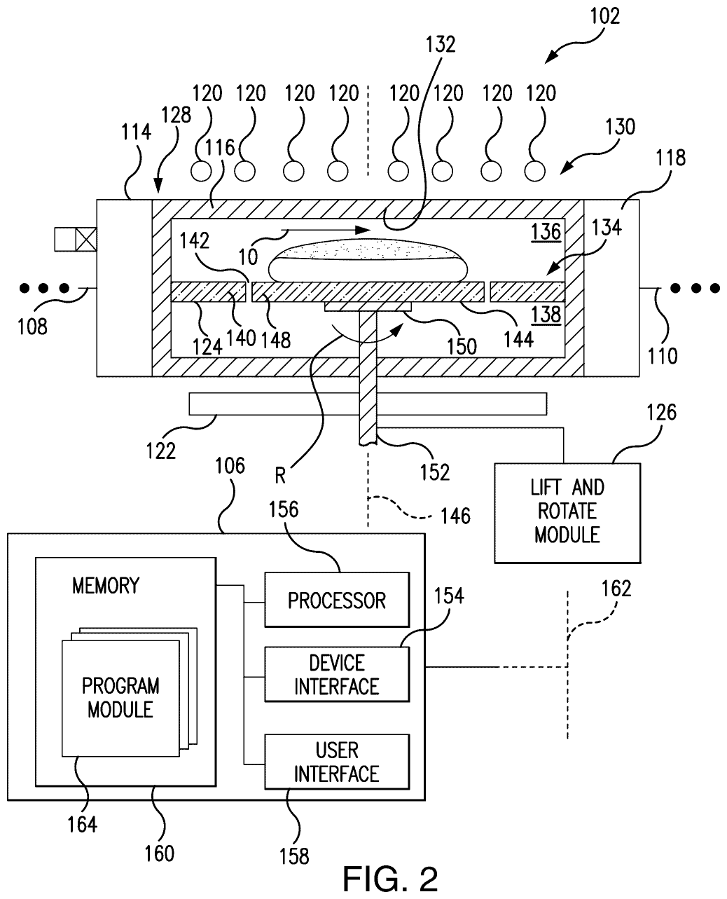

Reference will now be made to the drawings wherein like reference numerals identify similar structural features or aspects of the subject disclosure. For purposes of explanation and illustration, and not limitation, a partial view of an example of a liquid precursor container in accordance with the present disclosure is shown in FIG. 1 and is designated generally by reference characters 300. Other examples of liquid precursor containers, liquid precursor systems and semiconductor processing systems having liquid precursor containers, and methods of depositing material layers using vaporized liquid precursors in accordance with the present disclosure, or aspects thereof, are provided in FIGS. 2-12, as will be described. The systems and methods of the present disclosure may be used to deposit material layers onto substrates in gas phase reactors using vaporized liquid precursors, such as silicon-containing epitaxial material layers using vaporized silicon-containing and/or dopant-containing liquid layer precursors in single-wafer crossflow gas phase reactors, though the present disclosure is not limited any particular liquid precursor or reactor arrangement in general.

The description of exemplary embodiments provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of stated features.

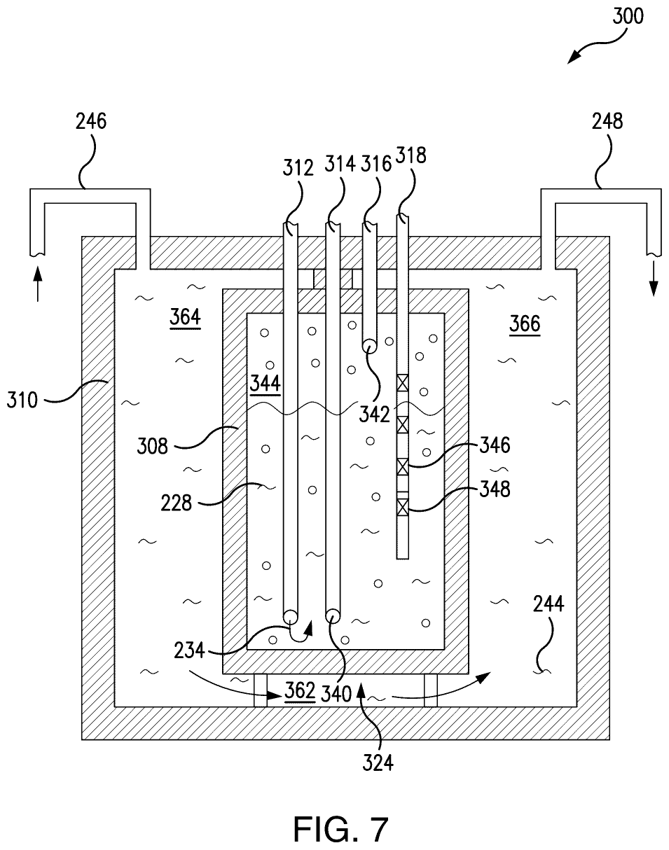

Referring to FIG. 1, a semiconductor processing system 100 is shown. The semiconductor processing system 100 includes a liquid precursor system 200 (e.g., a liquid precursor delivery system), a gas phase reactor 102, an exhaust source 104, and a controller 106. The liquid precursor system 200 is configured to provide a vaporized liquid precursor 10 to the gas phase reactor 102 and is connected to the gas phase reactor 102 by a precursor supply conduit 108. The gas phase reactor 102 is configured to deposit a material layer 4 onto a substrate 2 supported within the gas phase reactor 102 using the vaporized liquid precursor 10 and is connected to the exhaust source 104 by an exhaust conduit 110. The exhaust source 104 is configured to communicate residual precursor and/or reaction products 14 to the external environment 12, is fluidly coupled to an external environment 12 outside of the semiconductor processing system 100, and may include one or more of a vacuum pump and a scrubber or abatement apparatus 112. The controller 106 is operably connected to one or more of the liquid precursor system 200, the gas phase reactor 102, and the exhaust source 104 and in this respect may be configured to control vaporization of a liquid precursor 228 (shown in FIG. 7) contained within the liquid precursor container 300. In certain examples, the material layer 4 may include silicon and/or a dopant. In accordance with certain examples, the material layer 4 may be an epitaxial material layer. It is also contemplated that the material layer 4 may be an silicon-containing epitaxial material layer, which may also include a dopant.

As used herein the term “substrate” may refer to any underlying material or materials, including any underlying material or materials that may be modified, or upon which, a device, a circuit, or a film may be formed. A substrate may be continuous or non-continuous; rigid or flexible; solid or porous; and combinations thereof. A substrate may be in any form such as (but not limited to) a powder, a plate, or a workpiece. A substrate in the form of a plate may include a wafer in various shapes and sizes, for example, including 300-millimeter wafers.

A substrate may be formed from semiconductor materials, including, for example, silicon (Si), silicon-germanium (SiGe), silicon oxide (SiO₂), gallium arsenide (GaAs), gallium nitride (GaN) and silicon carbide (SiC). A substrate may include a pattern or may an unpatterned, blanket-type substrate. As examples, substrates in the form of a powder may have applications for pharmaceutical manufacturing. A porous substrate may include one or more polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, a continuous substrate may move through the process chamber such that the process continues until the end of the substrate is reached. A continuous substrate may be supplied from a continuous substrate feeding system to allow for manufacture and output of the continuous substrate in any appropriate form. Non-limiting examples of continuous substrates may include sheets, non-woven films, rolls, foils, webs, flexible materials, bundles of continuous filaments or fibers (for example, ceramic fibers or polymer fibers). A continuous substrate may also comprise a carrier or sheet upon which one or more non-continuous substrate is mounted.

With reference to FIG. 2, the gas phase reactor 102 and the controller 106 are shown according to an example of the present disclosure. In the illustrated example the gas phase reactor 102 has a single-wafer crossflow arrangement and in this respect includes an injection flange 114, a chamber body 116, and an exhaust flange 118. In further respect, the gas phase reactor 102 further includes an upper heater element array 120, a lower heater element array 122, a divider 124, and a lift and rotate module 126. Although shown and described herein as including certain elements and a having a specific arrangement, it is to be understood and appreciated that the gas phase reactor 102 may include other elements and/or exclude certain elements described herein, or have another arrangement, and remain within the scope of the present disclosure.

The chamber body 116 has an injection end 128 and a longitudinally opposite exhaust end 130, is formed from a transparent material 132 (e.g., a material transmissive to electromagnetic radiation within an infrared waveband), and may include a plurality of external ribs extending laterally about an exterior of the chamber body 116 and longitudinally spaced apart from one another between the injection end 128 and the exhaust end 130 of the chamber body 116. The injection flange 114 is connected to the injection end 128 of the chamber body 116 and fluidly couples the precursor supply conduit 108 to an interior 134 of the gas phase reactor 102. The exhaust flange 118 is connected to the exhaust end 130 of the chamber body 116, is further connected to the exhaust conduit 110, and fluidly couples the interior 134 of the chamber body 116 therethrough to the exhaust source 104 (shown in FIG. 1).

The upper heater element array 120 is supported above the chamber body 116 and includes a plurality of heater elements configured to heat a substrate (e.g., the substrate 2) when seated within the interior 134 of the chamber body 116. In this respect the plurality of heater elements of the upper heater element array 120 are configured to emit electromagnetic radiation within an infrared waveband, which the transparent material 132 communicates into the interior 134 of the chamber body 116. The lower heater element array 122 is similar to the upper heater element array 120, is additionally supported below the chamber body 116, and also configured to heat the substrate 2 during deposition of the material layer 4 (e.g., an epitaxial material layer) when the substrate 2 is seated within the interior 134 of the chamber body 116. In certain examples the upper heater element array 120 and the lower heater element array 122 may include linear filament heat lamps. In accordance with certain examples, the upper heater element array 120 and/or the lower heater element array 122 may include spot lamps and remain within the scope of the present disclosure.

The divider 124 is fixed within the chamber body 116 and divides the interior 134 of the chamber body 116 into an upper chamber 136 and a lower chamber 138. The divider 124 is further formed from an opaque material 140, e.g., a material opaque to electromagnetic radiation within an infrared waveband, and defines an aperture 142. It is contemplated that the aperture 142 fluidly coupled the upper chamber 136 of the chamber body 116 to the lower chamber 138 of the chamber body 116, and that a substrate support 144 be arranged within aperture 142. The substrate support 144 is configured to support the substrate 2 during deposition of the material layer 4 onto the substrate 2 and in this respect is supported for rotation R about a rotation axis 146 within the aperture 142. In further respect, the substrate support 144 may be formed from an opaque material 148, e.g., a material opaque to electromagnetic radiation within an infrared waveband, and may include a susceptor body. In certain examples, the opaque material 140 may include a bulk silicon carbide material. In accordance with certain examples, the opaque material 148 may include a bulk carbonaceous material with a silicon carbide material, such as bulk graphite or pyrolytic carbon by way of non-limiting example. It is also contemplated that, in accordance with certain examples, the substrate support 144 may be operably connected to the lift and rotate module 126 by a support member 150 and a shaft member 152, which may be arranged along the rotation axis 146 and fixed in rotation relative to the substrate support 144, and which may also be formed from the transparent material 132.

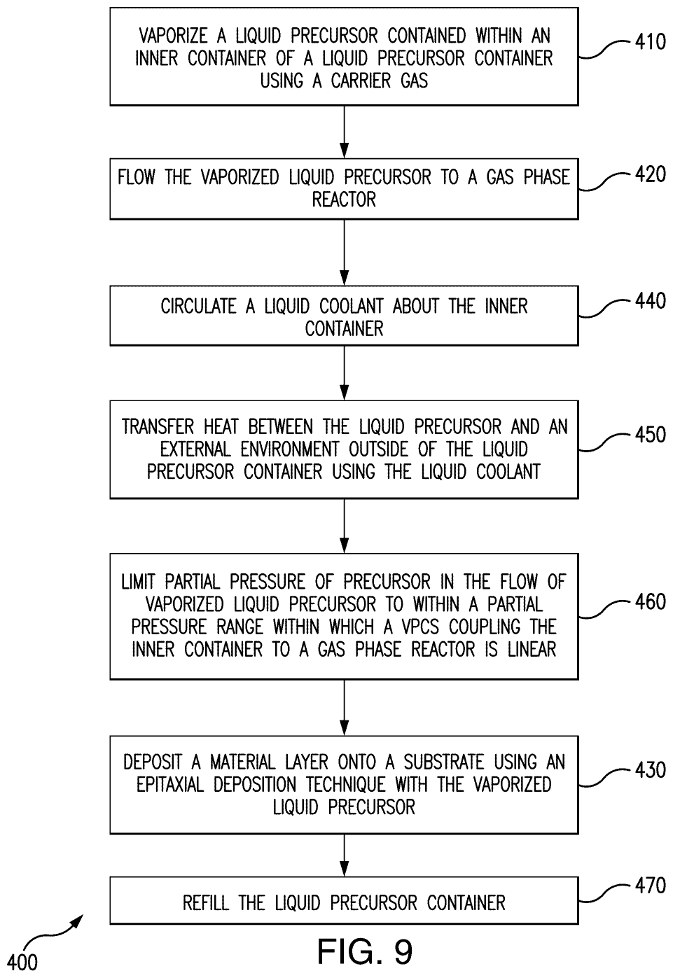

The controller 106 includes a device interface 154, a processor 156, a user interface 158, and a memory 160. The device interface 154 connects the processor 156 to a wired or wireless link 162 and therethrough to the liquid precursor system 200 and the gas phase reactor 102. The processor 156 is in turn operably connected to the user interface 158, for example, to receive a user input and/or provide a user output therethrough, and is disposed in communication with the memory 160. The memory 160 includes a non-transitory machine-readable medium having a plurality of program modules 164 recorded thereon that, when read by the processor 156, cause the processor 156 to execute certain operations. Among the operations are operations of a material layer deposition method 400 (shown in FIG. 9) using a liquid precursor, as will be described. Although shown and described herein as having a specific architecture, it is to be understood and appreciated that other controller architectures may be employed, e.g., distributed architectures, and remain within the scope of the present disclosure.

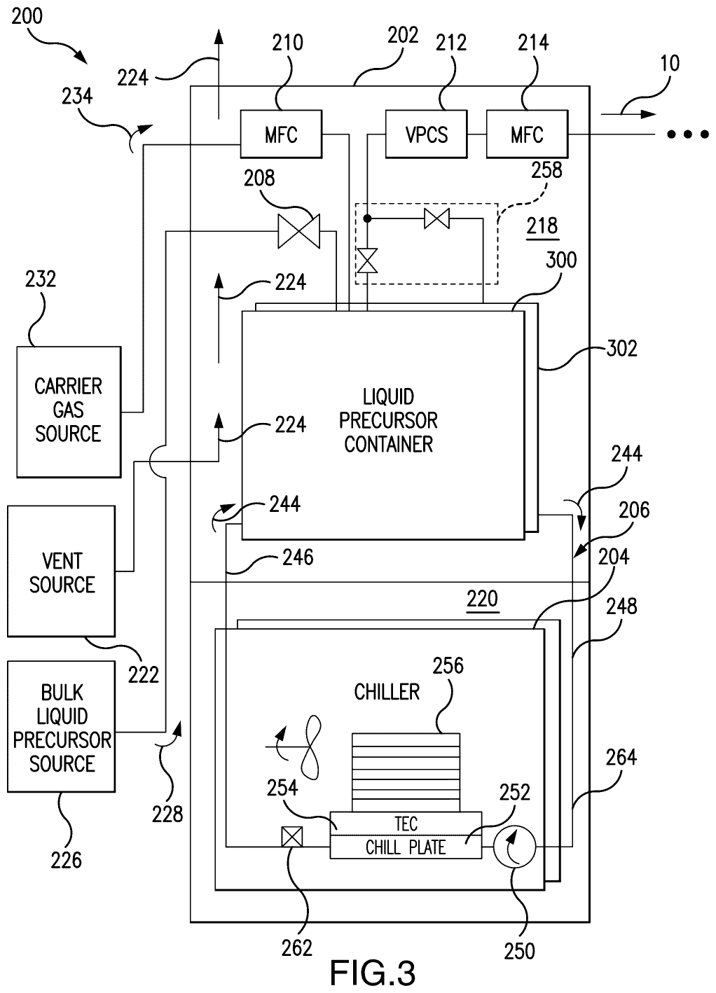

With reference to FIG. 3, the liquid precursor system 200 is shown according to an example. In the illustrated example the liquid precursor system 200 includes the liquid precursor container 300, an enclosure body 202, a chiller 204, and a coolant circuit 206. The liquid precursor system 200 also includes a refill valve 208 for in-situ refilling the liquid precursor container 300. The liquid precursor system 200 further includes a carrier gas mass flow controller (MFC) or pressure controller (PC) 210, a vapor pressure concentration sensor (VPCS) 212, and a vaporized liquid precursor MFC 214. Although shown and described herein as having certain elements and a particular arrangement, it is to be understood and appreciated that liquid precursor system 200 may include other elements and/or exclude elements shown and described herein in other examples, or have different arrangements, in other examples and remain within the scope of the present disclosure.

The enclosure body 202 is configured for arrangement proximate to (or within) the footprint of the semiconductor processing system 100 (shown in FIG. 1). In this respect it is contemplated that the enclosure body be arranged within about three (3) meters of the semiconductor processing system 100, for example, separated from the gas phase reactor 102 (shown in FIG. 1) by a spacing distance 216 (shown in FIG. 1) that is less than about three (3) meters. In accordance with certain examples, the enclosure body 202 may be supported above or below the semiconductor processing system 100 (indicated in dashed alternative outline in FIG. 1), for example above or below the gas phase reactor 102, a footprint of the liquid precursor system 200 overlaying a footprint of the semiconductor processing system 100. As will be appreciated by those of skill in the art, arranging the liquid precursor system 200 proximate the semiconductor processing system 100 limits size of the semiconductor processing system 100, limiting cost of the semiconductor processing system 100.

The enclosure body 202 defines an upper chamber 218 and a lower chamber 220 within an interior of the enclosure body 202. The upper chamber 218 overlays the lower chamber 220 and houses the liquid precursor container 300, the refill valve 208, the carrier gas MFC or PC 210, the VPCS 212, and the vaporized liquid precursor MFC 214. The lower chamber 220 houses the chiller 204 and is fluidly separated from the upper chamber 218. It is contemplated that the lower chamber 220 (and the chiller 204) be in fluid communication with the external environment 12 (shown in FIG. 1) outside of the semiconductor processing system 100 (shown in FIG. 1), for example, within a cleanroom environment within which the semiconductor processing system 100 is arranged. It is also contemplated that the upper chamber 218 may be fluidly isolated from the external environment 12 outside of the semiconductor processing system 100 (e.g., the cleanroom environment). In this respect the upper chamber 218 may be ventilated by a vent source 222, the vent source 222 connected to the enclosure body 202 and in fluid communication with the upper chamber 218 of the enclosure body 202, the vent source 222 configured to drive a flow of vent fluid 224 therethrough. As will be appreciated by those of skill in the art in view of the present disclosure, ventilating the upper chamber 218 limits risk potentially associated with fluid leakage from fluid-conveying structures arranged within the upper chamber 218 of the enclosure body 202 in the unlikely event that a leak develops.

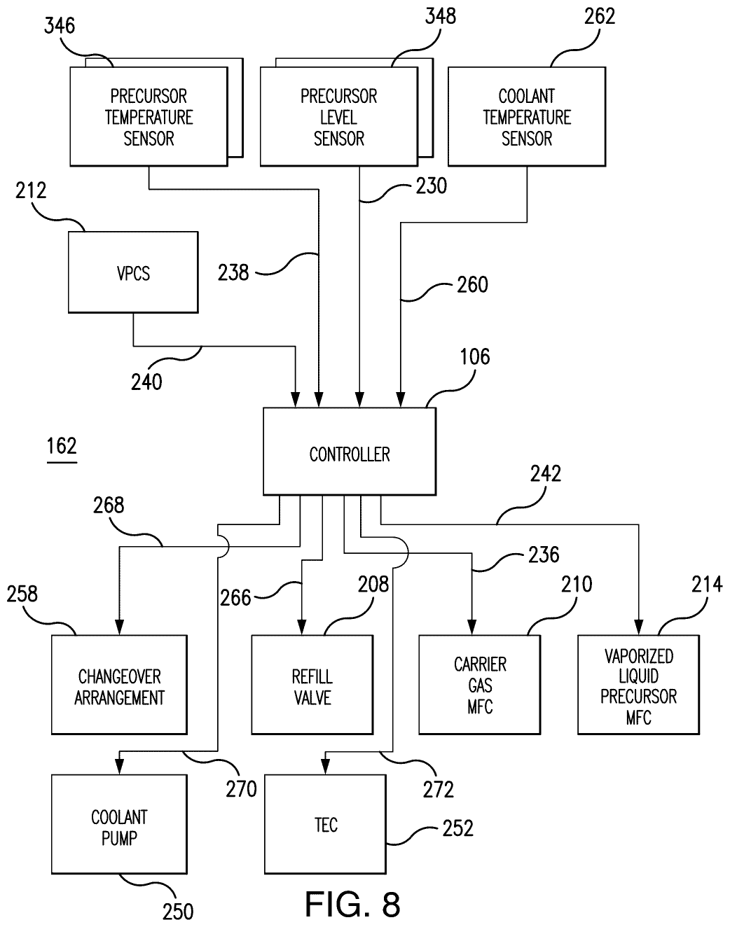

The refill valve 208 is connected to the liquid precursor container 300 and connects a bulk liquid precursor source 226 to the liquid precursor container 300. It is contemplated that the bulk liquid precursor source 226 contain a liquid precursor 228. It is also contemplated that the refill valve 208 be configured to fluidly couple the bulk liquid precursor source 226 to refill the liquid precursor container 300 with the liquid precursor 228. In this respect the refill valve 208 be operatively associated with the controller 106 (shown in FIG. 1), for example through the wired or wireless link 162 (shown in FIG. 1). The controller 106 may in turn be configured refill the liquid precursor container 300 when level of the liquid precursor 228 contained within the liquid precursor container 300 falls below a predetermined liquid precursor level value. For example, the controller 106 refill the liquid precursor container 300 using the refill valve 208 by comparing a liquid precursor level measurement 230 (shown in FIG. 8) to a predetermined liquid precursor level value and refilling the liquid precursor container 300 by comparing a liquid precursor level measurement 230 (shown in FIG. 8) received from the liquid precursor container 300 and refilling the liquid precursor container 300 when the liquid precursor level measurement 230 is less than the predetermined liquid precursor level value. In certain examples, the bulk liquid precursor source 226 may be remote from the semiconductor processing system 100 (shown in FIG. 1), e.g., outside of a cleanroom housing the semiconductor processing system 100, for example, in a support space such as a subfab space. As will be appreciated by those of skill in the art in view of the present disclosure, arranging the bulk liquid precursor source 226 from the semiconductor processing system 100 may limit risk to personnel and/or equipment otherwise associated with the liquid precursor 228.

In certain examples the liquid precursor 228 may comprise (e.g., consist of or consist essentially of) a silicon-containing liquid precursor such as trichlorosilane (Cl₃HSi). In accordance with certain examples, the liquid precursor may include a high order silane (i.e., a silane compound having more than two silicon atoms per molecule), such as a silicon-containing liquid precursor that enables deposition of a silicon-containing epitaxial material layer at a greater deposition rate than a silicon-containing gaseous precursor with two or less silicon atoms per molecule. Examples of suitable silicon-containing liquid precursors include trisilane (Si₃H₆) and/or tetrasilane (Si₄H₁₀). As will be appreciated by those of skill in the art in view of the present disclosure, employment of such silicon-containing liquid precursors allow the material layer 4 (shown in FIG. 1) to deposited at a high deposition relative to deposition processes employing silicon-containing gaseous precursors, enabling the semiconductor processing system 100 (shown in FIG. 1) to provide greater throughput and/or operate at lower deposition temperature rate than semiconductor processing systems employing silicon-containing gaseous precursors, limiting cost of ownership of the semiconductor processing system 100 relative to semiconductor processing systems.

In certain examples the liquid precursor 228 may comprise (e.g., consist of or consist essentially of) a dopant-containing liquid precursor. In this respect the liquid precursor 228 may include a p-type dopant such as boron (B), aluminum (Al), gallium (Ga), and indium (In). In further respect the liquid precursor 228 may include an n-type dopant such as phosphorous (P), arsenic (As), antimony (Sb), bismuth (Bi), and lithium (Li). In accordance with certain examples, the liquid precursor 228 may include a dopant that, when present in a gaseous precursor, requires containment features unnecessary when provided as a liquid precursor, such as tertiarybutylarsine (C₄H₁₁As). As will be appreciated by those of skill in the art in view of the present disclosure, this can limit the risk potentially associated with deposition processes employed to deposit material layers including such dopants. As will also be appreciated by those of skill in the art in view of the present disclosure, this can also simplify semiconductor processing systems employed to deposit such material layers by limiting (or eliminating) the need for safety features otherwise required where the dopant is provided using a gaseous precursor.

The carrier gas MFC or PC 210 is connected to the liquid precursor container 300 and connects a carrier gas source 232 to the liquid precursor container 300. It is contemplated that the carrier gas source 232 contain a carrier gas 234. It is also contemplated that the carrier gas MFC or PC 210 be configured to fluidly couple the carrier gas source 232 to the liquid precursor container 300 to vaporize the liquid precursor 228 using the carrier gas 234, for example by bubbling the carrier gas 234 through the liquid precursor 228 to vaporize a portion of the liquid precursor 228. In this respect the carrier gas MFC or PC 210 may be operatively associated with the controller 106 (shown in FIG. 1) and configured to provide a flow of the carrier gas 234 to the liquid precursor container 300 using a carrier gas flow rate target 236 (shown in FIG. 8) provided by the controller 106. In certain examples, the controller 106 may be further configured to determine the carrier gas flow rate target 236 using a liquid precursor temperature measurement 238 provided by the liquid precursor container 300, for example, for stabilizing temperature of the liquid precursor 228 following refill of the liquid precursor container 300. As will be appreciated by those of skill in the art in view of the present disclosure, stabilizing temperature of the liquid precursor 228 may limit interruption of operation of the semiconductor processing system 100 (shown in FIG. 1) otherwise potentially associated with refill of the liquid precursor container 300.

In certain examples, the carrier gas 234 may include an inert gas such as nitrogen (N₂) gas. In accordance with certain examples, the carrier gas 234 may include a noble gas such as helium (He), argon (Ar), krypton (Kr) or a mixture including one or more of the aforementioned noble gases. It is also contemplated that the carrier gas 234 may include hydrogen (H₂) gas and remain within the scope of the present disclosure.

The VPCS 212 and the vaporized liquid precursor MFC 214 are connected to the liquid precursor container 300 and connect the liquid precursor container 300 to the gas phase reactor 102 (shown in FIG. 1). It is contemplated that the VPCS 212 and the vaporized liquid precursor MFC 214 be configured to provide the flow of the vaporized liquid precursor 10 to the gas phase reactor 102, for example, in cooperation with the flow of the carrier gas 234 provided to the liquid precursor container 300 by the carrier gas MFC or PC 210. In this respect it is contemplated that the VPCS 212 may be disposed in communication with the controller 106 via the wired or wireless link 162 (shown in FIG. 1) to provide thereto a precursor partial pressure measurement 240 (shown in FIG. 8), which may be representative of partial pressure of vaporized liquid precursor resident within a precursor ullage space 344 within the liquid precursor container 300, and which may be acquired from within the flow of vaporized liquid precursor 10 traversing the outlet conduit 316. In further respect, it is contemplated that the vaporized liquid precursor MFC 214 also may be operably associated with the controller 106, e.g., through the wired or wireless link 162, to throttle flow rate of the flow of the vaporized liquid precursor 10 using a vaporized liquid precursor flow rate target 242 (shown in FIG. 8). It is contemplated that the controller 106 calculate the vaporized liquid precursor flow rate target 242 using a flow rate of the vaporized liquid precursor 10 required for the deposition of the material layer 4 (shown in FIG. 1) onto the substrate 2 (shown in FIG. 1) and the precursor partial pressure measurement 240 received from the VPCS 212, for example, received from the user interface 158 (shown in FIG. 2) or from within a recipe received at the device interface 154 (shown in FIG. 2). Examples of suitable MFC devices include GP200 Series MFC devices, available from Brooks Instrument, LLC. of Hatfield, Pennsylvania. Examples of suitable VPCS devices include IR-300 vapor concentration monitor devices, available from Horiba Ltd. of Kyoto, Japan.

The coolant circuit 206 connects the chiller 204 to the liquid precursor container 300 and is configured to provide a liquid coolant 244 to the liquid precursor container 300 through a coolant supply conduit 246 and return the liquid coolant 244 to the chiller 204 through a coolant return conduit 248. The chiller 204 includes a coolant pump 250, a chill plate 252, a thermoelectric cooler (TEC) 254, and a heat sink 256. The coolant pump 250 is configured to drive the liquid coolant 244 through the chill plate 252 and the liquid precursor container 300 via the coolant supply conduit 246 and the coolant return conduit 248. The chill plate 252 connects the coolant return conduit 248 to the coolant supply conduit 246 and thermally couples the liquid coolant 244 to the TEC 254. The TEC 254 is connected to the chill plate 252 thermally couples the chill plate 252 to the heat sink 256. The heat sink 256 may include a pinned or finned body and may be configured to transfer heat between the liquid precursor 228 contained within the liquid precursor container 300 and the external environment 12 (shown in FIG. 1) outside of the liquid precursor container 300, for example, between the liquid precursor 228 and a cleanroom environment housing the semiconductor processing system 100 (shown in FIG. 1).

In certain examples the liquid coolant 244 may include water. In accordance with certain examples the liquid coolant 244 may include one or more of glycol and alcohol. It is also contemplated that, in accordance with certain examples, the liquid coolant 244 may include a perfluorinated compound. Examples of suitable perfluorinated compounds in Fluorinert®, available from the 3M Company of Maplewood, Minnesota. Advantageously, it is contemplated that arrangement of liquid precursor container 300 be such that use of liquid coolants potentially reactive with the liquid precursor 228 have substantially no impact on the safety risk analysis of the liquid precursor system 200.

In certain examples, either (or both) the heat sink 256 and the coolant pump 250 may be operatively associated with the controller 106 (shown in FIG. 1) to throttle transfer of heat between liquid precursor container 300 and the external environment outside of the liquid precursor container 300, for example via fan speed and/or pump speed using a fan speed and/or pump speed target 270 (shown in FIG. 8). In accordance with certain examples, the TEC 254 may be operatively associated with the controller 106 to throttle transfer of heat between the liquid precursor container 300 and the external environment outside of the liquid precursor container 300. For example, the controller 106 may compare the liquid precursor temperature to a predetermined liquid precursor value and throttle heat transfer between the liquid precursor 286 contained within the liquid precursor container 300 and the external environment with a TEC current flow signal 272 (shown in FIG. 8). Advantageously, throttling rate of heat transfer via the TEC 254 enables relatively fine change in rate of heat transfer change in relation the fan speed and/or pump speed changes, enabling temperature control sufficient to maintain the partial pressure of vaporized liquid precursor resident within the precursor ullage space 344 (shown in FIG. 7) within a range wherein the VPCS 212 is linear. It is also contemplated that throttling may be accomplished using a coolant temperature measurement 260 (shown in FIG. 8) provided by a coolant temperature sensor 262 included in the chiller 204 and thermally coupled to the coolant circuit 206. As will be appreciated by those of skill in the art in view of the present disclosure, this enables control of mass flow of precursor within the vaporized liquid precursor 10 (shown in FIG. 1) sufficient limit variation in the material layer 4 (shown in FIG. 1) deposited onto the substrate 2 (shown in FIG. 1) to within that required by semiconductor devices fabricated using the material layer 4.

The liquid precursor container 300 is configured to vaporize the liquid precursor 228 using the carrier gas 234 and may be configured as a bubbler, e.g., by bubbling the carrier gas 234 through the liquid precursor 228 to vaporize the liquid precursor 228, to provide the flow of vaporized liquid precursor 10 to the gas phase reactor 102 (shown in FIG. 1). The liquid precursor 228 may be permanently affixed within the upper chamber 218 of the enclosure body 202 and configured for refilling therein in-situ, i.e., without removal of the liquid precursor container 300 from the enclosure body 202. As will be appreciated by those of skill in the art in view of the present, permanent affixation within the upper chamber 218 of the enclosure body 202 may limit risk otherwise associated with the liquid precursor, for example, by limiting risk that residual precursor infiltrate the upper chamber 218 during removal of a liquid precursor container for refill.

In certain examples, the liquid precursor container 300 may be a first liquid precursor container 300 and the liquid precursor system 200 may include a second liquid precursor container 302. The second liquid precursor container 302 may be similar to the first liquid precursor container 300 and connected to the first liquid precursor container 300 by a changeover arrangement 258. The changeover arrangement 258 may be configured to switch source of the flow of the vaporized liquid precursor 10 provided to the gas phase reactor 102 (shown in FIG. 1) between the first liquid precursor container 300 and the second liquid precursor container 302, for example, during refill events. In this respect it is contemplated that the controller 106 may further be configured to switch source of the flow of the vaporized liquid precursor 10 from one of the first liquid precursor container 300 and the second liquid precursor container 302 to the other of the first liquid precursor container 300 and the second liquid precursor container 302 when the liquid precursor level measurement 230 is less than the predetermined liquid precursor value.

In certain examples, the chiller 204 may be a first chiller 204 and the liquid precursor system 200 may include a second chiller 264. The second chiller 264 may be similar to the first chiller 204 and additionally connected to the second liquid precursor container 302, the second chiller enabling temperature control of liquid precursor contained within the second liquid precursor container 302 independent of that contained within the first liquid precursor container 300. As will be appreciated by those of skill in the art in view of the present disclosure, examples of the liquid precursor system 200 including more than one liquid precursor container may limit (or eliminate) interruption of operation of the gas phase reactor 102, limiting cost of ownership of the semiconductor processing system 100 (shown in FIG. 1).

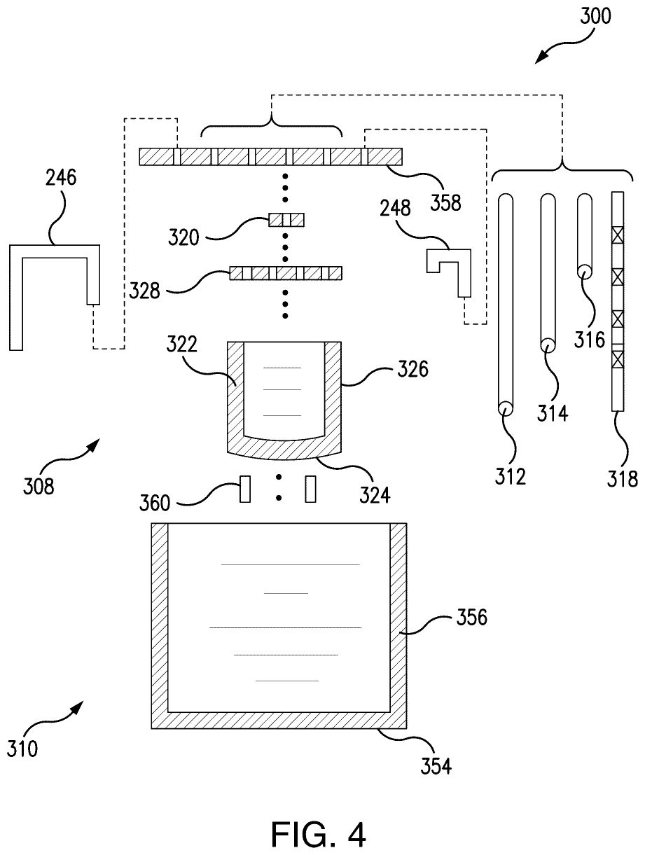

With reference to FIGS. 4-7, the liquid precursor container 300 is shown in an exploded view according to an example of the present disclosure. As shown in FIG. 4, the liquid precursor container 300 includes an inner container 308 and an outer container 310. The liquid precursor container 300 also includes a carrier gas conduit 312, a refill conduit 314, an outlet conduit 316, a probe member 318, and a baffle member 320. Although shown and described herein as having certain elements it is to be understood and appreciated that the liquid precursor container 300 may include additional elements and/or omit elements shown and described herein, and remain within the scope of the present disclosure.

The inner container 308 is configured to contain the liquid precursor 228 (shown in FIG. 3) and in this respect may be formed from a metallic material 322. It is contemplated that the inner container 308 further have an inner base portion 324, an inner intermediate portion 326, and an inner lid portion 328. The inner base portion 324 extends laterally within the outer container 310 and may define an arcuate or cupped profile. The inner intermediate portion 326 extends upwards from the inner base portion 324 (e.g., vertically relative to gravity) and about a periphery of the inner base portion 324 of the inner container 308. The inner lid portion 328 of the inner container 308 is connected the inner intermediate portion 326 of the inner container 308, such as at a weld, and is coupled by the inner intermediate portion 326 to the inner base portion 324 of the inner container 308. It is contemplated that the inner container 308 be configured for vaporization of the liquid precursor 228 (shown in FIG. 7) contained therein by bubbling the carrier gas 234 (shown in FIG. 3) through the liquid precursor 228 to vaporize a portion of the liquid precursor 228 contained within the inner container 308.

In certain examples, the metallic material 322 forming the inner container 308 may be a stainless steel material. For example, the inner container 308 may be formed from 316L stainless steel, which limits (or eliminates) risk of contamination of the material layer 4 (shown in in FIG. 1) deposited onto the substrate 2 (shown in FIG. 1) due to corrosion of the inner container 308. In accordance with certain examples, the inner container 308 may be formed such that the inner container 308 complies with a U.S. Department of Transportation regulation. For example, the inner container 308 may be DOT 4B-complaint and/or 49 C.F.R. § 178 (2021)-complaint. Advantageously, compliance to such regulations and/or standards allows the inner container 308 to be immersed within the liquid coolant 244 (shown in FIG. 3) notwithstanding the liquid precursor 228 (shown in FIG. 3) being reactive with the liquid coolant 244.

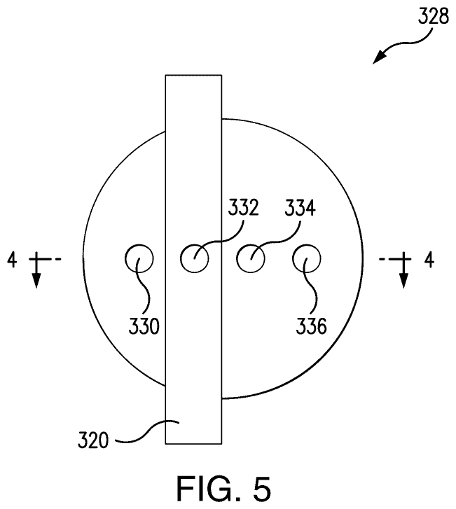

As shown in FIG. 5, the inner lid portion 328 of the inner container 308 (shown in FIG. 4) defines an inner carrier gas aperture 330, an inner refill aperture 332, an inner outlet aperture 334, and an inner probe member aperture 336. The inner carrier gas aperture 330 extends through a thickness of the inner lid portion 328 and couples an exterior surface of the inner lid portion 328 to an interior surface of the inner lid portion 328. As shown in FIG. 7, it contemplated that the inner carrier gas aperture 330 (shown in FIG. 5) receive therethrough the carrier gas conduit 312, the carrier gas conduit 312 extending within an interior of the inner container 308 toward the inner base portion 324 of the inner container 308 and terminating at a carrier gas outlet 338 proximate the inner base portion 324 of the inner container 308. It is further contemplated that the carrier gas conduit 312 be sealably received within the inner carrier gas aperture 330 to communicate the carrier gas 234 into the interior of the inner container 308 while fluidly separating the liquid coolant 244 circulated about the exterior of the inner container 308 from the liquid precursor 228 contained within the inner container 308. In certain examples, the carrier gas conduit 312 may be sealably fixed within the inner carrier gas aperture 330 by a fluid-tight fitting. In accordance with certain examples, the carrier gas conduit 312 may be sealably fixed within the inner carrier gas aperture 330 by a fluid-tight fitting and/or with a seal member. As will be appreciated by those of skill in the art in view of the present disclosure, other sealing structures may be employed and remain within the scope of the present disclosure.

With continuing reference to FIG. 5, the inner refill aperture 332 is similar to the inner carrier gas aperture 330 and is additionally offset from the inner carrier gas aperture 330. As shown in FIG. 7, it contemplated that the inner refill aperture 332 (shown in FIG. 5) receive therethrough the refill conduit 314. The refill conduit 314 in turn extends into the interior of the inner container 308 and toward the inner base portion 324 of the inner container 308. It is further contemplated that the refill conduit 314 terminate at refill conduit outlet 340 laterally offset from the carrier gas outlet 338 and proximate the inner base portion 324 of the inner container 308, and that the refill conduit 314 be sealably received within the inner refill aperture 332 for refilling the inner container 308 with liquid precursor.

In certain examples, the refill conduit 314 may be sealably fixed within the inner refill aperture 332 by weld. In accordance with certain examples, the refill conduit 314 by be sealably fixed within the inner refill aperture 332 by a fluid-tight fitting and/or with a sealing member. It is also contemplated that, in accordance with certain examples, the refill conduit outlet 340 may be registered to a center of the inner base portion 324 of the inner container 308, limiting (or eliminating) the need to allow time for liquid precursor settling following refill events. As will be appreciated by those of skill in the art in view of the present disclosure, other sealing structures may be employed and remain within the scope of the preset disclosure.

Referring again to FIG. 5, the inner outlet aperture 334 and the inner probe member aperture 336 are also similar to the inner carrier gas aperture 330, are further separated from the inner carrier gas aperture 330 by the inner refill aperture 332, and are additionally configured to sealably receive therein the outlet conduit 316 (shown in FIG. 4) and the probe member 318 (shown in FIG. 4), respectively. In the illustrated example the inner outlet aperture 334 is further separated from the inner carrier gas aperture 330 by the baffle member 320, the inner probe member aperture 336 is laterally offset from the inner outlet aperture 334, and the baffle member 320 separates both the inner outlet aperture 334 and the inner probe member aperture 336 from the inner carrier gas aperture 330. As shown and described herein the inner apertures 330-336 are arranged along a singular diameter spanning the inner lid portion 328 of the inner container 308. As will be appreciated by those of skill in the art in view of the present disclosure, two or more of the aforementioned inner apertures may be arranged along an arc or a circumference (e.g., to simplify packaging) defined on the inner lid portion 328 of the inner container 308, for example to facilitate packaging of the inner container 308 within the outer container 310 and remain within the scope of the present disclosure.

As shown in FIG. 7, it is contemplated that outlet conduit 316 be sealably fixed within the inner outlet aperture 334 (shown in FIG. 5), such as with a weld or fluid-tight fitting. In this respect it is contemplated that the outlet conduit 316 have an outlet conduit inlet 342 and that the outlet conduit inlet 342 be arranged within a precursor ullage space 344 defined between a surface of the liquid precursor 228 contained within the inner container 308 and the inner lid portion 328 of the inner container 308. In certain examples, the outlet conduit inlet 342 may be flush with an interior surface of the inner lid portion 328 of the inner container 308. As will be appreciated by those of skill in the art in view of the present disclosure, offsetting the outlet conduit inlet 342 limits entrainment of liquid precursor within the flow of vaporized liquid precursor 10 (shown in FIG. 1) provided to the gas phase reactor 102 (shown in FIG. 1), such in the event that vaporized liquid precursor condenses on an interior surface of the inner lid portion 328 of the inner container 308. As will also be appreciated by those of skill in the art in view of the present disclosure, fixing the outlet conduit 316 within the inner outlet aperture 334 such that the outlet conduit inlet 342 is flush with an inner surface of the inner lid portion 328 limits height of the liquid precursor container 300, simplifying packaging the liquid precursor container 300 within the enclosure body 202 of the liquid precursor system 200.

It is also contemplated that the probe member 318 be sealably fixed within the inner probe member aperture 336. In this respect it is contemplated that the probe member 318 extend through the precursor ullage space 344 and toward the inner base portion 324 of the inner container 308 such that a tip of the probe member 318 is proximate the inner base portion 324 of the inner container 308. In the illustrated example the probe member 318 includes one or more precursor temperature sensor 346 and one or more liquid precursor level sensor 348. The one or more precursor temperature sensor 346, is disposed in communication with the controller 106 (shown in FIG. 1) through the wired or wireless link 162 (shown in FIG. 1), and configured to provide the liquid precursor temperature measurement 238 to the controller 106. The one or more liquid precursor level sensor 348 is also arranged along the length of the probe member 318, may overlay (or underlie) the one or more precursor temperature sensor 346, and is configured to provide the liquid precursor level measurement 230 (shown in FIG. 8). In certain examples, the probe member 318 may include a plurality of precursor temperature sensors 346 (e.g., thermocouples and/or resistance temperature detectors) each arranged along a length of the probe member 318 and overlaying one another. In accordance with certain examples, the probe member 318 may include a plurality of liquid precursor level sensors 348 arranged along the length of the probe member 318 and overlaying one another along the length of the probe member 318. As will be appreciated by those of skill in the art in view of the present disclosure, incorporation of more than one precursor temperature sensor and/or more than one level sensor may improve reliability of the liquid precursor system 200 (shown in FIG. 2), for example, by enabling matching of vaporized liquid precursor temperature with liquid precursor temperature or liquid precursor temperature with vaporized liquid precursor temperature.

Referring again to FIG. 4 and with continuing reference to FIG. 7, the outer container 310 is configured to sealably envelope the inner container 308 and in this respect has an outer base portion 354, an outer intermediate portion 356, and an outer lid portion 358. The outer base portion 354 of the outer container 310 laterally spans the inner base portion 324 of the inner container 308, and is spaced apart from the inner base portion 324 of the inner container 308 by a turning plenum 362 defined therebetween. In certain examples, the inner base portion 324 of the inner container 308 may be supported within the outer container 310 by a plurality of standoffs 360 arranged within the turning plenum 362.

The outer intermediate portion 356 of the outer container 310 extends upwards from the outer base portion 354 of the outer container 310 and about the inner container 308, and is spaced apart from the inner intermediate portion 326 of the inner container 308. It is contemplated that the outer intermediate portion 356 extend above the inner lid portion 328 of the inner container 308 such that a rim of the outer intermediate portion 356 is spaced apart from the inner base portion 324 of the inner container 308 by the inner lid portion 328 of the inner container 308. In certain examples, the inner intermediate portion 326 may be at least partially coupled to the inner intermediate portion 326 of the inner container 308 by the baffle member 320. In this respect the baffle member 320 may divide a gap defined between the interior surface of the outer intermediate portion 356 and the exterior surface of the inner intermediate portion 326 into a supply plenum 364 and a return plenum 366 separated by the baffle member 320. In certain examples, the outer container 310 may be formed of the same material as the inner container 308. In accordance with certain examples, the outer container 310 may be formed from a different material than the inner container 308. It is also contemplated that, in accordance with certain examples, the outer container 310 may not be a DOT 4B-compliant container.

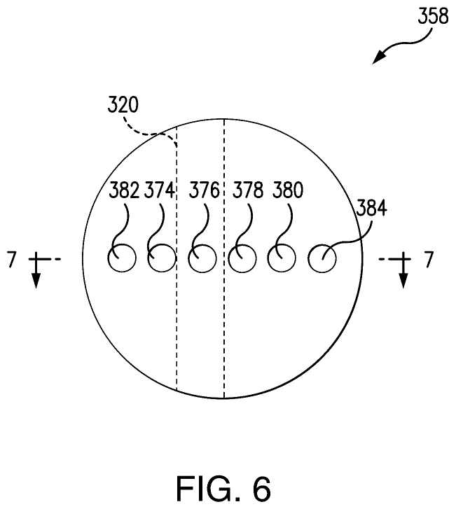

As shown in FIG. 6, the outer lid portion 358 of the outer container 310 (shown in FIG. 4) defines an outer carrier gas aperture 374, an outer refill aperture 376, an outer outlet aperture 378, and an outer probe member aperture 380. The outer carrier gas aperture 374 extends through a thickness of the outer lid portion 358 of the outer container 310 (shown in FIG. 4), couples an exterior surface of the outer lid portion 358 to an interior surface of the outer lid portion 358, and receives therethrough the carrier gas conduit 312 (shown in FIG. 4). In this respect it is contemplated that the outer carrier gas aperture 374 be registered to the inner carrier gas aperture 330 (shown in FIG. 5), and that the carrier gas conduit 312 be sealably fixed within the outer carrier gas aperture 374. The outer refill aperture 376, the outer outlet aperture 378, and the outer probe member aperture 380 are similar to the outer carrier gas aperture 374 and are additionally registered to the inner refill aperture 332 (shown in FIG. 5), the inner outlet aperture 334 (shown in FIG. 5), and the inner probe member aperture 336 (shown in FIG. 5), respectively; and further sealably fix therein the refill conduit 314 (shown in FIG. 4), the outlet conduit 316 (shown in FIG. 4), and the probe member 318 (shown in FIG. 4), respectively. Although shown and described herein as having an inner refill aperture 332 and an outer refill aperture 374, it is to be understood and appreciated that the inner refill aperture 332 and the outer refill aperture 374 may be plugged, for example with a singular or dual plug arrangement, in examples where the liquid precursor container 300 is refilled ex-situ (i.e., at a location remote from the semiconductor processing system including the liquid precursor container 300).

It is contemplated that the outer lid portion 358 further define a coolant supply aperture 382 and a coolant return aperture 384. The coolant supply aperture 382 sealably seats therein the coolant supply conduit 246 (shown in FIG. 3) and fluidly couples the coolant supply conduit 246 to the supply plenum 364. The coolant return aperture 384 is fluidly separated from the coolant supply aperture 382 by the baffle member 320, seats therein the coolant return conduit 248 (shown in FIG. 3), and fluidly couples the coolant return conduit 248 to the return plenum 366 and therethrough to the supply plenum 364 via the turning plenum 362. This allows the coolant pump 250 (shown in FIG. 3) to drive the liquid coolant 244 through the liquid precursor 228 and about a totality of the exterior of the inner container 308, promoting temperature uniformity throughout the interior of the liquid precursor container 300 (i.e., both a volume occupied by the liquid coolant 244 and a volume of the precursor ullage space 344 occupied by evaporated liquid precursor).

With reference to FIG. 8, inputs to and outputs from the controller 106 are shown according to examples of the present disclosure. It is contemplated that one or more of the precursor temperature sensor 436, the one or more liquid precursor level sensor 348, the VPCS 212, and the coolant temperature sensor 262 be disposed in communication with the controller 106, for example, through the wired or wireless link 162. In certain examples, the one or more precursor temperature sensor 346 may be configured to provide the 238 liquid precursor temperature measurement 238 to the controller 106. In accordance with certain examples, the one or more liquid precursor level sensor 348 may be configured to provide the liquid precursor level sensor 348 to the controller 106. It is contemplated that, in certain examples, the VPCS 212 may be configured to provide the precursor partial pressure measurement 240 to the controller 106. It is also contemplated that, in accordance with certain examples, the coolant temperature sensor 262 may be configured to provide the coolant temperature measurement 260 to controller 106. Although shown in FIG. 8 as receiving four (4) measurements, it is to be understood and appreciated that the controller 106 may receive fewer or additional measurements than shown in FIG. 8 and remain within the scope of the present disclosure.

The controller 106 may be operatively connected to one or more of the changeover arrangement 258, the refill valve 208, the carrier gas MFC or PC 210, the vaporized liquid precursor MFC 214, the coolant pump250, and the TEC 254, for example, through the wired or wireless link 162. In certain examples, the controller 106 may be configured to provide a refill signal 266 to the refill valve 208. In accordance with certain examples, the controller 106 may be configured to provide a changeover signal 268 to the changeover arrangement 258. It is contemplated that, in certain examples, the controller 106 may be configured to provide the carrier gas flow rate target 236 to the carrier gas MFC or PC 210. It is also contemplated that, in accordance with certain examples, the controller 106 may be configured to provide the vaporized liquid precursor flow rate target 242 to the vaporized liquid precursor MFC 214. It is further contemplated that the controller 106 may be configured to provide a fan and/or pump speed target 270 to the coolant pump 250 and/or the TEC current flow signal 272 to the TEC 254. Although shown in FIG. 8 and described herein as providing five (5) control signals, it is to be understood and appreciated that the controller 106 may provide fewer or additional control signals than shown in FIG. 8 and remain within the scope of the present disclosure.

In certain examples, the controller 106 may receive the liquid precursor level measurement 230 from the one or more liquid precursor level sensor 348. The controller may compare the liquid precursor level measurement 230 to a predetermined liquid precursor level value, for example to a predetermined precursor level value recorded on the memory 160 (shown in FIG. 2), and refill the liquid precursor container 300 (shown in FIG. 1) when the liquid precursor level measurement 230 is less than the predetermined liquid precursor level value. Refilling may be accomplished by sending the refill signal 266 to the refill valve 208, for example, by energizing a solenoid or pneumatic actuator included in the refill valve 208. In accordance with certain examples, the controller 106 may also switch source of the flow of vaporized liquid precursor 10 (shown in FIG. 1) from one of the first liquid precursor container 300 and the second liquid precursor container 302 (shown in FIG. 3) to the other of the first liquid precursor container 300 and the second liquid precursor container 302. As will be appreciated by those of skill in the art in view of the present disclosure, refilling the liquid precursor container 300 when level of the liquid precursor 228 contained within the liquid precursor container 300 falls below the predetermined liquid precursor level may limit interruption to operation of the gas phase reactor 102 (shown in FIG. 1) that could otherwise result from vaporization of the liquid precursor 228 contained within the liquid precursor container 300. As will also be appreciated by those of skill in the art in view of the present disclosure, changing source of the vaporized liquid precursor 10 may also limit interruption of the gas phase reactor 102, for example, by providing time for stabilizing temperature of the liquid precursor 228 contained within the liquid precursor container 300 following a refill event.

In certain examples, the controller 106 may receive the liquid precursor temperature measurement 238 from the one or more precursor temperature sensor 346. The controller 106 may compare the liquid precursor temperature measurement 238 to a predetermined liquid precursor temperature valve, for example a predetermined liquid precursor temperature measurement value recorded on the memory 160, and throttle heat transfer between the liquid precursor 228 (shown in FIG. 3) and the external environment outside of the liquid precursor container 300 when a differential between the liquid precursor temperature measurement 238 and the predetermined liquid precursor temperature value exceeds a predetermined differential value. Throttling may be accomplished by increasing or decreasing an electric current applied to the TEC 254, such as by using the TEC current flow signal 272. Throttling may be accomplished by increasing or decreasing fan and/or pump speed thermally coupled to the liquid precursor 228, for example using the fan and/or pump speed target 270. Advantageously, throttling heat transfer using the TEC 254 can provide relatively fine control of heat transfer relatively to fan and/or pump speed, enabling maintenance of precursor partial pressure within the ullage space 377 to within a range wherein the VPCS 212 is sufficiently accurate (e.g., linear) to control mass flow rate of vaporized liquid precursor entrained within the flow of the vaporized liquid precursor 10 (shown in FIG. 1) provided to the gas phase reactor 102 (shown in FIG. 1) for the deposition process employed therein.

In certain examples, the controller 106 may receive the precursor partial pressure measurement 240 from the VPCS 212. The precursor partial pressure measurement 240 may be compared to a predetermined precursor concentration value and flow rate of the carrier gas 234 (shown in FIG. 3) provided to the liquid precursor container 300 throttled when the precursor partial pressure measurement 240 differs from the predetermined precursor concentration value by more than a predetermined concentration differential value. Throttling may be accomplished using the carrier gas flow rate target 236 provided to the carrier gas MFC or PC 210, for example by determining carrier gas flow rate target using the precursor partial pressure measurement 240. In accordance with certain examples, the carrier gas flow rate target may adjust using the liquid precursor level measurement 230, for example, by increasing (in relative terms) the carrier gas flow rate value when volume of the ullage space 377 (shown in FIG. 7) is relatively large relative to volume immediately after a refill event.

In certain examples, precursor partial pressure measurement 240 may be compared to a predetermined precursor concentration value and flow rate of the vaporized liquid precursor 10 (shown in FIG. 1) throttled when the precursor partial pressure measurement 240 differs from the predetermined precursor concentration value by more than the predetermined concentration differential value. Throttling of the flow rate of the vaporized liquid precursor 10 may be accomplished using the vaporized liquid precursor flow rate target 242 provided to the carrier gas MFC or PC 210 by the controller 106, for example by determining a vaporized liquid precursor flow rate target using the precursor partial pressure measurement 240. In accordance with certain examples, the determined vaporized liquid precursor flow rate target may be adjusted using the liquid precursor level measurement 230, for example, by increasing (in relative terms) the flow rate of the vaporized liquid precursor 10 when volume of the ullage space 377 (shown in FIG. 7) is relatively large relative to volume immediately after a refill event. It is also contemplated that flow rate of the carrier gas 234 (shown in FIG. 3) may also be adjusted, as described above, coincident with adjustment of flow rate of the vaporized liquid precursor 10 to the gas phase reactor 102. As will be appreciated by those of skill in the art in view of the present disclosure, adjusting flow rate of the vaporized liquid precursor 10 and/or the carrier gas 234 may limit precursor concentration variation within the flow of vaporized liquid precursor 10 provided to the gas phase reactor 102, limiting variation potentially otherwise possible due to concentration changing to a level outside that where the VPCS 212 is accurate.

With reference to FIGS. 9-12, the material layer deposition method 400 is shown. As shown in FIG. 9, the method 400 includes vaporizing a liquid precursor contained within an inner container of a liquid precursor container using a carrier gas, e.g., the liquid precursor 228 (shown in FIG. 3) contained within the inner container 308 (shown in FIG. 4) of a liquid precursor container 300 (shown in FIG. 1), using the carrier gas 234 (shown in FIG. 3), as shown with box 410. The method 400 also includes flowing the vaporized liquid precursor into a gas phase reactor, e.g., the vaporized liquid precursor 10 (shown in FIG. 1) into the gas phase reactor 102 (shown in FIG. 1), as shown with box 420. The method 400 further includes depositing a material layer onto a substrate, e.g., the material layer 4 (shown in FIG. 1) onto the substrate 2 (shown in FIG. 1), using an epitaxial deposition technique with the vaporized liquid precursor, as shown with box 430. It is contemplated that a liquid coolant, e.g., the liquid coolant 244 (shown in FIG. 3), be circulated about the inner container during vaporization of the liquid precursor and the liquid coolant transfer heat between the liquid precursor and an external environment outside of the liquid precursor container, as shown with box 440 and box 450. It is also contemplated the liquid coolant circulated about the inner container may limit partial pressure of precursor in the flow of vaporized liquid precursor to within a partial pressure range within which a VPCS in communication with the flow of the vaporized liquid precursor, e.g., the VPCS 212 (shown in FIG. 3), responds linearly to change in partial pressure of vaporized liquid precursor within the flow of vaporized liquid precursor, as shown with box 460, and the that the liquid precursor container may be refilled in-situ (i.e., without removal), as shown with box 470.

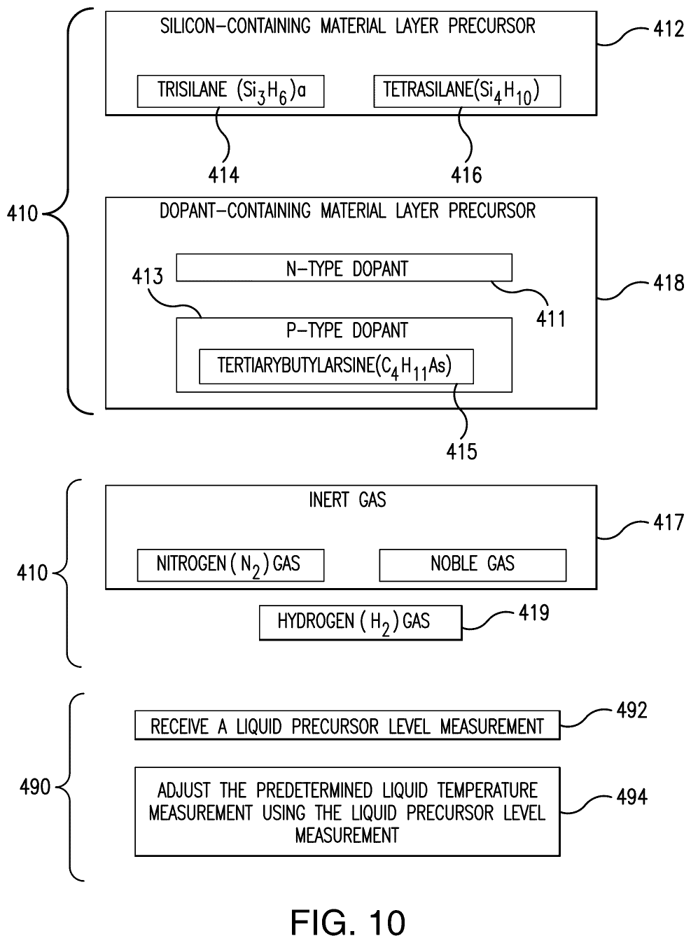

As shown in FIG. 10, the liquid precursor may include a silicon-containing material layer precursor, as shown with box 412. In this respect the liquid precursor contained within the inner container of the liquid precursor container may include (or consist of or consist essentially of) a high order silane, such as trisilane (Si₃H₆) or tetrasilane (Si₄H₁₀), as shown with box 414 and box 416. In accordance with certain examples, the liquid precursor may include a dopant-containing material layer precursor, as shown with box 418. For example, the dopant-containing material layer precursor may include (or consist of or consist essentially of) a p-type dopant or an n-type dopant, as shown with box 411 and box 413. Examples of suitable dopants include tertiarybutylarsine (C₄H₁₁As), as shown with box 415, though phosphorous-containing and/or boron-containing dopants are also possible and remain within the scope of the present disclosure.

It is contemplated that the carrier gas employed to vaporize the liquid precursor may include an inert gas, as shown with box 417. The inert gas may include nitrogen (N₂) gas and/or a noble gas, as also shown with box 417. It is also contemplated that the carrier gas may include hydrogen (H₂) gas, as shown with box 419, and remain within the scope of the present disclosure. In certain examples, the carrier gas may be bubbled through the liquid precursor, the carrier gas vaporizing a portion of the liquid precursor as the carrier gas bubbles through the liquid precursor and into an ullage space, e.g., the ullage space 377 (shown in FIG. 7), defined within the liquid precursor container. It is further contemplated that the material layer deposited onto the substrate using the vaporized liquid precursor may be deposited using an epitaxial deposition technique, and that deposition of the material layer may include incorporating one or more dopants into the epitaxial material layer during deposition of the material layer onto the substrate.

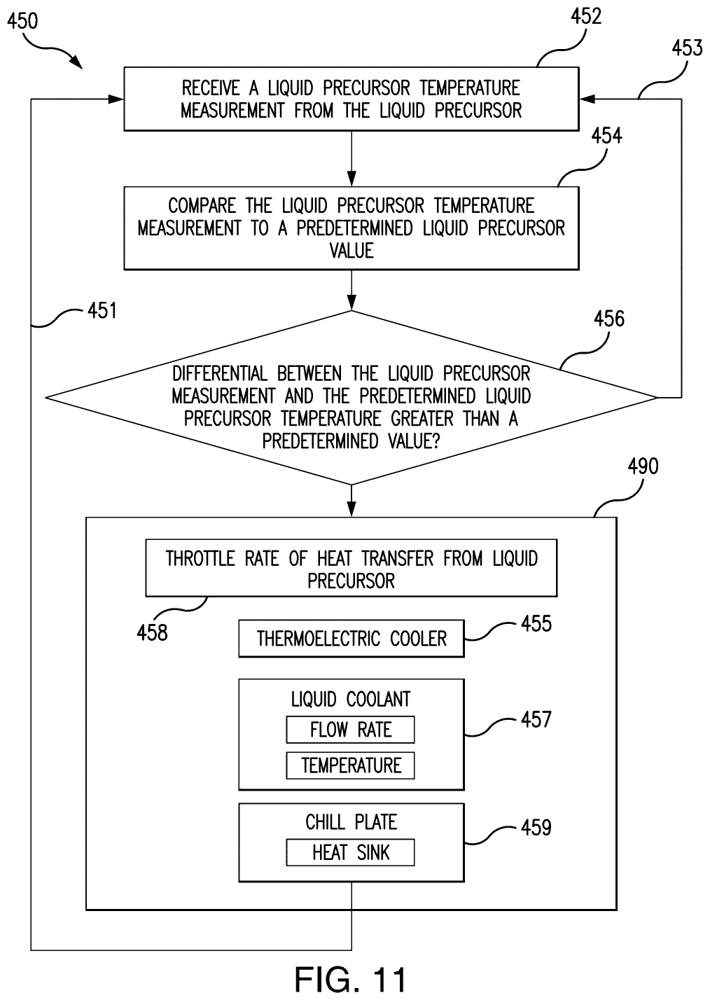

As shown in FIG. 11, transferring 450 heat between the liquid precursor and an external environment outside of the liquid precursor container, e.g., the external environment 12 (shown in FIG. 1), may include receiving a liquid precursor temperature measurement, e.g., the liquid precursor temperature measurement 238 (shown in FIG. 8), as shown with box 452. The liquid precursor temperature measurement may be compared to a predetermined liquid precursor temperature measurement, e.g., a predetermined liquid precursor temperature measurement recorded on the memory 160 (shown in FIG. 2), as shown with box 454. When a differential between the liquid precursor temperature measurement and the predetermined liquid precursor value differs by more than a predetermined value rate of heat transfer between the liquid precursor and the external environment may be throttled, as shown with box 456 and box 458, and monitoring thereafter continue, as show with arrow 451. When the differential differs by less than the predetermined value no action may be taken, and monitoring may continue, as shown with box 456 and arrow 453.

Throttling of heat transfer between the liquid precursor and the external environment may be accomplished using a TEC, as shown with box 455. Throttling of heat transfer between the liquid precursor may accomplished using flow rate of the liquid coolant, as shown with box 457. Throttling of heat transfer between the liquid coolant and the external environment may also be accomplished by varying airflow across a heat sink, as shown with box 459. In certain examples, throttling may be accomplished by adjusting the predetermined liquid precursor target to compensate for change in volume of an ullage space occupied by vaporized liquid precursor during draw down of the liquid precursor contained within the liquid precursor container, as shown with box 490. In this respect, as shown in FIG. 10, a liquid precursor level measurement may be received indicative of liquid precursor level within the liquid precursor container, and the predetermined liquid precursor temperature target or liquid precursor temperature measurement adjusted using the liquid precursor level measurement, as shown with box 492 and box 494.

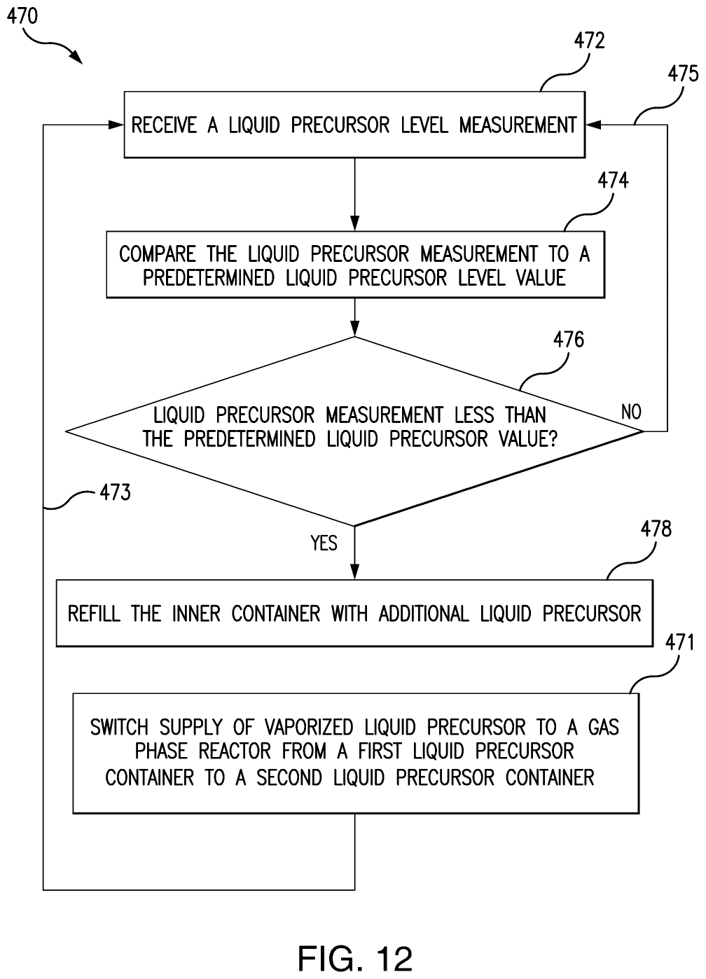

As shown in FIG. 12, refilling 470 the liquid precursor container may include receiving a liquid precursor measurement indicative of level of liquid precursor within the liquid precursor container, e.g., the liquid precursor level measurement 230 (shown in FIG. 8), as shown with box 472. The liquid precursor measurement may be compared to a predetermined liquid precursor level, for example a predetermined liquid precursor level recorded on the memory 160 (shown in FIG. 2), as shown with box 474, and the inner container of the liquid precursor container refilled when the liquid precursor measurement is less than the predetermined liquid precursor value, as shown with box 476 and box 478. It is contemplated that the source of vaporized liquid precursor provided to the gas phase reactor may be switched from one of a first liquid precursor source and a second liquid precursor to the other of the first liquid precursor source and the second liquid precursor source when the liquid precursor measurement is less than the predetermined liquid precursor value, as shown with box 471. It is also contemplated that the monitoring of liquid precursor level may continue subsequent to refill of the liquid precursor and/or when liquid precursor level is greater than the predetermined liquid precursor level, as shown with arrow 473 and arrow 475.

Material layers are commonly deposited onto substrates during the fabrication of semiconductor devices, such silicon-containing epitaxial layers. While generally acceptable for their intended purpose, flow rate of gaseous state silicon-containing precursors to reactors employed for silicon-containing layer deposition may be constrained the fluid system employed to provide the gaseous state silicon-containing precursor to the substrate, potentially requiring that relatively high temperature deposition processes be employed for throughput reasons.

One alternative to gaseous state silicon-containing precursors is the employment of liquid state silicon-containing precursors. Liquid state silicon-containing precursors typically have greater numbers of silicon atoms per molecule relative to the gaseous state silicon-containing precursors, potentially enabling greater deposition rates and/or deposition of silicon-containing material layers at relatively low temperature. However, liquid state precursors commonly bring with them the need for cooling, such as with water baths and/or water-filled cooling jackets, and the need for safety countermeasures due to the tendency of liquid state silicon-containing precursors to react with water (and other coolants generally), potentially posing a hazard to personnel and equipment in the unlikely event that liquid state silicon-containing precursor leaks and reacts with the coolant employed to cool the liquid state silicon-containing precursor.

In examples described liquid precursor containers are employed to provide flows of vaporized liquid precursors to gas phase reactors. In certain examples, the liquid precursor container may include an inner container enveloped within an outer container. The inner container may contain a liquid precursor through which a carrier gas is bubbled to make-up the flow of vaporized liquid precursor provided to the gas phase reactor, and the outer container may circulate a liquid coolant about the inner container to control temperature of the liquid precursor during vaporization of the liquid precursor. In certain examples the inner container may be an DOT 4B-compliant container, limiting risk of liquid precursor leakage, enabling the employment of liquid coolants in proximity to liquid precursor reactive with the liquid coolant. In accordance with certain examples, heat transfer may be throttled in substantially real-time using liquid precursor temperature measurements and/or liquid precursor measurements acquired from within the inner container and a TEC thermally coupling the liquid precursor to the external environment. Advantageously, temperature control may be such that partial pressure of vaporized liquid precursor resident within the liquid precursor container remains within a range wherein a VPCS used to control vaporized liquid precursor flow to a gas phase reactor is accurate (e.g., is linear).

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

The headings provided herein, if any, are for convenience only and do not necessarily affect the scope or meaning of the devices and methods disclosed herein.

1. A liquid precursor container, comprising:
an inner container having an inner base portion, an inner intermediate portion extending from the inner base portion, and an inner lid portion coupled to the inner base portion by the inner intermediate portion;
an outer container enveloping the inner container and having an outer base portion spaced apart from the inner base portion of the inner container, an outer intermediate portion extending from the outer base portion and about the inner intermediate portion of the inner container, and an outer lid portion coupled to the outer base portion by the outer intermediate portion; and
a baffle member arranged between the inner lid portion of the inner container and the outer lid portion of the outer container to circulate a liquid coolant about the inner container to cool a liquid precursor contained within the inner container during vaporization of the liquid precursor.

2. The liquid precursor container of claim 1, wherein the liquid precursor includes at least one of trisilane (Si₃H₆), tetrasilane (Si₄H₁₀), tertiarybutylarsine (C₄H₁₁As).

3. The liquid precursor container of claim 1, further comprising a probe member extending through the outer lid portion of outer container and the inner lid portion of the inner container to provide a liquid precursor temperature measurement and a liquid precursor level measurement of the liquid precursor contained within the inner container.

4. The liquid precursor container of claim 1, further comprising a carrier gas conduit extending through the outer lid portion of the outer container and the inner lid portion of the inner container to vaporize the liquid precursor using a carrier gas issued into the liquid precursor by the carrier gas conduit.

5. The liquid precursor container of claim 1, further comprising a refill conduit extending through the outer lid portion of the outer container and the inner lid portion of the inner container to refill the inner container with the liquid precursor when level of the liquid precursor falls below a predetermined liquid precursor level.

6. The liquid precursor container of claim 1, further comprising:
a coolant supply conduit connected to the outer lid portion of the outer container;
a coolant return conduit connected to the outer lid portion of the outer container and fluidly coupled to the coolant supply conduit by an exterior surface of the inner container; and
a coolant pump connected to the coolant supply conduit and the coolant return conduit to circulate the liquid coolant about the exterior surface of the inner container,
wherein the baffle member separates the coolant return conduit from the coolant supply conduit.

7. The liquid precursor container of claim 6, further comprising a chill plate fluidly coupling the coolant supply conduit to the coolant return conduit to transfer heat between the liquid precursor contained within the inner container and an external environment outside of the liquid precursor container.

8. The liquid precursor container of claim 6, further comprising a thermoelectric cooler thermally coupled to the liquid precursor by the coolant supply conduit and the coolant return conduit to throttle rate of heat transfer between the liquid precursor contained within the liquid precursor container and an external environment outside of the liquid precursor container.

9. The liquid precursor container of claim 1, further comprising an outlet conduit extending through the outer lid portion of the outer container and seated in the inner lid portion of the inner container to fluidly couple a gas phase reactor to a precursor ullage space defined between the liquid precursor and the inner lid portion of the inner container.

10. The liquid precursor container of claim 9, further comprising a vapor pressure concentration sensor connected to the outlet conduit to provide a precursor partial pressure measurement acquired from within a flow of vaporized liquid precursor traversing the outlet conduit.

11. The liquid precursor container of claim 10, further comprising a vaporized liquid precursor mass flow controller arranged along the outlet conduit to throttle flow rate of the flow of the vaporized liquid precursor traversing the outlet conduit.

12. The liquid precursor container of claim 9, further comprising a gas phase reactor having a single-wafer crossflow arrangement connected to the outlet conduit to deposit an epitaxial material layer onto a substrate seated within the gas phase reactor using the flow of the vaporized liquid precursor traversing the outlet conduit.

13. The liquid precursor container of claim 1, further comprising:
a controller including a processor and a memory connected to the liquid precursor container, the processor responsive to instructions recorded on the memory to:
receive a liquid precursor temperature measurement;
compare the liquid precursor temperature to a predetermined liquid precursor temperature value; and
throttle heat transfer between the liquid precursor and an external environment outside of the liquid precursor container based on a differential between the liquid precursor temperature measurement and the predetermined liquid precursor temperature value,
whereby partial pressure of vaporized liquid precursor within a flow of vaporized liquid precursor issued from the liquid precursor container is within a range within which a vapor pressure concentration sensor fluidly coupled to the flow is linear.

14. The liquid precursor container of claim 13, wherein the instructions recorded on the memory further cause the controller to:
receive a liquid precursor level measurement indicative of level of the liquid precursor contained within the inner container; and
adjust the predetermined liquid precursor temperature value using the liquid precursor level measurement,
whereby the partial pressure of the vaporized liquid precursor within the flow of the vaporized liquid precursor remains within the range during drawdown of the liquid precursor contained within the inner container.

15. The liquid precursor container of claim 13, wherein the instructions recorded on the memory further cause the controller to:
receive a liquid precursor level measurement indicative of level of the liquid precursor contained within the inner container;
compare the liquid precursor level measurement to a predetermined liquid precursor value; and
refill the inner container with the liquid precursor when the liquid precursor level measurement is less than the predetermined liquid precursor value.

16. The liquid precursor container of claim 1, wherein the baffle member divides a gap defined between the outer container and the inner container into:
a coolant supply plenum extending between the inner lid portion and the inner base portion of the inner container;
a coolant return plenum extending between the inner base portion and the inner lid portion of the inner container; and
a turning plenum defined between the outer base portion of the outer container and the inner base portion of the inner container, the turning plenum fluidly coupling the coolant return plenum to the coolant supply plenum.

17. A liquid precursor system, comprising:
an enclosure body having an upper chamber and a lower chamber;
a first liquid precursor container and a second liquid precursor container as recited in claim 1 arranged within the upper chamber;
a changeover arrangement connecting the first liquid precursor container and the second liquid precursor container to a precursor supply conduit; and
a controller operably connected to the changeover arrangement and responsive to instructions recorded on a memory to:
receive a liquid precursor level measurement from the first liquid precursor container;
fluidly couple the second liquid precursor container to the precursor supply conduit using the changeover arrangement when the liquid precursor level measurement is less than a predetermined liquid precursor level; and
refill the first liquid precursor container when the liquid precursor level measurement is less than the predetermined liquid precursor level.

18. A semiconductor processing system, comprising:
a liquid precursor container as recited in claim 1;
a precursor supply conduit connected to the liquid precursor container; and
a gas phase reactor connected to the precursor supply conduit and therethrough to the liquid precursor container.

19. The semiconductor processing system of claim 18, wherein the liquid precursor container is spaced apart from the gas phase reactor by less than about 3 meters.

20. A material layer deposition method, comprising:
at liquid precursor container including an inner container having an inner base portion, an inner intermediate portion extending from the inner base portion, and an inner lid portion coupled to the inner base portion by the inner intermediate portion; an outer container enveloping the inner container and having an outer base portion spaced apart from the inner base portion of the inner container, an outer intermediate portion extending from the outer base portion and about the inner intermediate portion of the inner container, and an outer lid portion coupled to the outer base portion by the outer intermediate portion; and a baffle member arranged between the inner lid portion of the inner container and the outer lid portion of the outer container,
vaporizing a liquid precursor contained within the inner container using a carrier gas;
flowing the vaporized liquid precursor to a gas phase reactor;
depositing a material layer onto a substrate using an epitaxial deposition technique with the vaporized liquid precursor;
circulating a liquid coolant about the inner container and through the liquid precursor container; and
transfer heat between the liquid precursor and an external environment outside of the liquid precursor container using the liquid coolant to limit partial pressure of precursor in the flow of vaporized liquid precursor to within a partial pressure range within which a vapor pressure concentration sensor responds linearly to precursor partial pressure change within the flow of vaporized liquid precursor.
